(19) United States
(12) Patent Application Publication
(10) Pub. No.: US 2025/0002376 A1
(43) Pub. Date: Jan. 2, 2025

(54) PLASMA WATER TREATMENT

(71) Applicant: Plasmaleap Technologies Pty Ltd, Marrickville (AU)

(72) Inventor: Patrick Joseph CULLEN, Sydney (AU)

(21) Appl. No.: 18/808,858

(22) Filed: Aug. 19, 2024

Related U.S. Application Data
(63) Continuation of application No. 17/837,307, filed on Jun. 10, 2022, now abandoned.
Application No. 17/837,307 is a continuation of application No. PCT/AU2020/051323, filed on Dec. 3, 2020.

(30) Foreign Application Priority Data
Dec. 11, 2019 (AU) 2019904694

(51) Int. Cl. C02F 1/46; C02F 101/30; C02F 101/36; H05H 1/24

(52) U.S. Cl. CPC C02F 1/4608; H05H 1/2441; H05H 1/247; C02F 2101/305; C02F 2101/36; C02F 2201/003; C02F 2201/46; C02F 2303/04; C02F 2305/023; H05H 2245/20

(57) ABSTRACT

An apparatus is provided for treating a liquid with a plasma. The apparatus includes one or two dielectric barriers, and the dielectric barrier(s) and high voltage electrode define a discharge zone therebetween. A high voltage electrode may be electrically insulated from the discharge zone by the inner dielectric barrier. In this apparatus, the outer dielectric barrier is gas and the discharge zone is configured to accept a gas flow therethrough.

### CROSS REFERENCE TO RELATED APPLICATIONS

This application is a continuation of U.S. patent application Ser. No. 17/837,307, filed Jun. 10, 2022, which is a continuation of International Application No. PCT/AU2020/051323, filed Dec. 3, 2020, which takes priority from Australian Provisional Patent Application No. 2019904694, filed Dec. 11, 2019, the entire contents of each of which are incorporated by reference herein.

### TECHNICAL FIELD

The present invention relates to an apparatus and a method for treating water with a plasma, to water treated with a plasma and to methods of using the plasma treated water.

The invention has been developed primarily for use in water treatment and will be described hereinafter with reference to this application. However, it will be appreciated that the invention is not limited to this particular field of use.

### BACKGROUND

Reactive species produced by plasma are known to be effective for the breakdown of certain biological and chemical materials that may be present in water. Water exposed to plasma derived reactive species may also be “activated” by introducing a range of reactive metastable species into the water. This Plasma Activated Water (PAW) may be used to treat materials exposed to it, so as to provide product decontamination including microbial, fungal, viral and chemical. The PAW may be used as a fertilizer or as a fuel.

A variety of reactive species are produced by plasma and plasma-water reactions including hydroxyl radicals, hydroperoxyl radicals, hydrogen peroxide, ozone, excited molecules and excited atoms via various pathways. An essential factor in sterilization is the presence of reactive species produced in plasma during treatment. These reactive species can be classified into two main types: primary reactive species, such as charged particles, photons, and certain radicals (·H, ·O, ·OH, ·NO) and secondary (H2O2, NOx, O3, HNOx, and ONOOH).

Primary reactive species, are created when atmospheric gases are subjected to high voltages. Hydroxyl radical is the core component in advanced oxidative processes due to their substantially instantaneous and non-selective reaction with pollutants including nondegradable organics and volatile organic compounds. Hence, OH radical production is critical for water treatment efficiency by plasma.

However, due to their high reactivity, OH radical has a short lifetime often attributed to dimerization of OH radical to produce the secondary reactive species hydrogen peroxide, which in turn has been applied to water treatment process for disinfection and sterilization. Hydrogen peroxide is preferred over chlorine treatment as it does not produce toxic by-products in oxidation reactions.

Most water treatment efforts have focused on generating the secondary reactive species ozone (O₃). O₃ has been used to treat organic pollutants degradation in water treatment and it selectively attacks unsaturated bonds and partly degrades organic compounds. O₃ is usually generated by an electrical discharge through air in a discharge passage and the liquid to be treated is received within the discharge passage and thereby directly exposed to the O₃ generated.

An O₃ disinfection system strives for maximum solubility of O₃ in wastewater, as disinfection depends on the transfer of O₃ to the wastewater. In conventional ozone generators, the DBD is separated from the water and ozone is linked via tubing allowing diffusion into the water. The dispersed energetic electrons can increase the production of reactive species, especially UV light, O, and O3. However, the production of OH radicals and H₂O₂ by DBD reactors does not show competitive results compared with other gas discharge types.

In Wang et al., there is taught a device that combines a dielectric barrier discharge plasma with a microporous aeration device, which disperses O₃ formed within the confines of the dielectric discharge barrier (DBD) reactor to absorb into a surrounding liquid. As shown, the reactor in Wang et al., represents a type of O₃ generator typical of DBD discharge reactors including a means for improving mass transfer of O₃ in liquid medium for disinfection treatment.

O₃ generators/reactors have a number of drawbacks including:
Low dosage may not effectively inactivate some viruses, spores, and cysts.
Ozonation is a more complex technology than is chlorine or UV disinfection, requiring complicated equipment and efficient contacting systems.
O₃ is very reactive and corrosive, thus requiring corrosion-resistant material such as stainless steel.
Ozonation is not economical for wastewater with high levels of suspended solids (SS), biochemical oxygen demand (BOD), chemical oxygen demand, or total organic carbon.
O₃ is extremely irritating and possibly toxic, so off-gases from the contactor must be destroyed to prevent worker exposure.

The plasma may be interfaced with the water via direct discharge to its surface, underwater discharge, discharge within submerged gas bubbles or via introduction of the reactive gas species as bubbles to the water bulk. The manner in which the plasma generated in a gas phase is interfaced with the water, such as in a pre-existing bubble, over a liquid surface, or when latter is in the form of water sprays and droplets, significantly affects the chemical make-up of the species produced owing to different breakdown strength in the gas phase and solution, respectively.

It is desirable to provide a reactor means for producing primary reactive OH radicals and enabling effective reaction time of the OH radicals produced with a treatment liquid.

In addition to the foregoing, scaling of atmospheric plasma technology has proven to be challenging due to the need to effectively introduce the short-lived reactive species from the gas plasma to the water. The present invention seeks to provide an apparatus which will overcome or substantially ameliorate at least some of the deficiencies of the prior art, or to at least provide an alternative.

It is to be understood that, if any prior art information is referred to herein, such reference does not constitute an admission that the information forms part of the common general knowledge in the art, in Australia or any other country.

### SUMMARY

According to a first aspect, there is provided an apparatus for treating a liquid with a plasma, said apparatus comprising a first dielectric barrier and a second dielectric barrier, said first and second dielectric barriers defining a discharge zone therebetween, and a high voltage electrode which is electrically insulated from the discharge zone by the first dielectric barrier. In this aspect, the second dielectric barrier is gas-permeable and the discharge zone is configured to accept a gas flow therethrough.

The following options may be used in conjunction with the first aspect, either individually or in any suitable combination,

The apparatus may additionally comprise an earthed electrode. The earthed electrode may be separated from the discharge zone by at least the second dielectric barrier. The earthed electrode and the discharge zone may be on opposite sides of the second dielectric barrier.

The apparatus may additionally comprise a vessel for containing a liquid. In use, the liquid in the vessel may be in contact with the second dielectric barrier. The liquid may be separated from the discharge zone by the second dielectric barrier. In the present specification, the term “separated from . . . by”, for example “A is separated from B by C”, indicates that at least a portion of C is disposed between A and B such that A does not contact B. It does not imply that C is the only integer between A and B, although in certain instances it may be.

In one option, the vessel comprises a dielectric material, and the apparatus comprises an earthed electrode in contact with the dielectric material. The earthed electrode may be disposed such that, in use, said dielectric material separates the liquid in the vessel from the earthed electrode. Thus the earthed electrode may be disposed on the outside of the vessel. In this instance, in use, the liquid would be contained inside the vessel.

In another option, the apparatus comprises an earthed electrode, which is disposed such that, in use, said earthed electrode is in electrical contact with the liquid in the vessel. In one form, the vessel is electrically conducting and comprises or forms the earthed electrode. In yet another option, a separate metallic earthed electrode is disposed within the liquid in the vessel, optionally disposed on an inside surface of the vessel.

The high voltage electrode may be disposed within the first dielectric barrier. It may be surrounded by, enclosed in, or encased in, the first dielectric barrier. In one configuration, the high voltage electrode, the first dielectric barrier, the discharge zone and the second dielectric barrier are concentric. The high voltage electrode may be surrounded by the first dielectric barrier, which is surrounded by the discharge zone, which is in turn surrounded by the second dielectric barrier.

The first dielectric barrier may be gas-impermeable. It may be impermeable to a gas used in the discharge zone. It may be impermeable to the liquid.

The second dielectric barrier may be porous. It may be microporous. It may be permeable to any one or more of a gas in the discharge zone, the plasma species and the discharge itself. It may be hydrophobic. Alternatively it may be hydrophilic. It may have non-porous and/or gas impermeable regions, provided that at least part thereof is porous and/or gas permeable.

The apparatus may comprise a gas inlet. This may enable a gas or gas mixture to enter the discharge zone. In some instances the discharge zone has a gas outlet but in other instances the second (gas-permeable) dielectric barrier serves as the only gas outlet. The apparatus may comprise a gas propulsion device, e.g. a pump, for passing a gas into the discharge zone through the gas inlet. In some instances, all of the gas entering the discharge zone exits the discharge zone through the outer dielectric barrier.

The apparatus may comprise a high voltage generator. This may be capable of applying a voltage to the high voltage electrode sufficient to generate a plasma in a gas in the discharge zone. The voltage may be between about 1 kV RMS (root mean square) and about 150 kV RMS. The high voltage generator may be electrically coupled to, and/or in electrical contact with, the high voltage electrode.

In an embodiment, there is provided an apparatus for treating a liquid with a plasma, said apparatus comprising a first dielectric barrier which is gas impermeable and a second dielectric barrier which is porous, said first and second dielectric barriers defining a discharge zone therebetween, and a high voltage electrode which is electrically insulated from the discharge zone by the first dielectric barrier. In this embodiment, the discharge zone is configured to accept a gas flow therethrough.

In another embodiment there is provided an apparatus for treating a liquid with a plasma, said apparatus comprising: a first dielectric barrier which is gas impermeable and a second dielectric barrier which is porous, said first and second dielectric barriers defining a discharge zone therebetween, a high voltage electrode which is electrically insulated from the discharge zone by the first dielectric barrier and encased therein, and a high voltage generator capable of applying a voltage to the high voltage electrode sufficient to generate a plasma in a gas in the discharge zone, said voltage commonly being between about 1 kV RMS and about 150 kV RMS.

In this embodiment the discharge zone is configured to accept a gas flow therethrough

In a second aspect, there is provided a method for treating a liquid with a plasma. This method comprises providing an apparatus according to the first aspect, passing a gas through the discharge zone, exposing a side of the second dielectric barrier away from the discharge zone to the liquid; and applying a voltage to the high voltage electrode sufficient to generate a plasma in the gas in the discharge zone.

The following options may be used in conjunction with the second aspect, either individually or in any suitable combination.

The gas may be any one of air, nitrogen, oxygen, carbon dioxide, helium, neon, argon, xenon or it may be a mixture of any two or more of these. For example, the gas may be air.

The liquid may be an aqueous liquid. It may be water.

The pressure difference across the second dielectric barrier may be sufficient to cause the gas to pass from the discharge zone into the liquid.

The voltage may be between about 1 kV RMS and about 150 kV RMS.

The liquid may comprise one or more contaminants. In this case, the method may at least partially remove and/or destroy the contaminant(s). The contaminant(s) may be microorganisms or may be viruses or may be chemical contaminants, or the water may have any two or more of viral, microbial and chemical contaminants. In a particular example, the contaminant comprises PFAS (per- and/or poly-fluoroalkyl substances). In another example it comprises one or more of pharmaceuticals, endocrine disruptors and PFAS.

In one embodiment, the method comprises: providing an apparatus for treating a liquid with a plasma, said apparatus comprising a first dielectric barrier and a second dielectric barrier, said first and second dielectric barriers defining a discharge zone therebetween, and a high voltage electrode which is electrically insulated from the discharge zone by the first dielectric barrier, wherein the second dielectric barrier is gas-permeable and the discharge zone is configured to accept a gas flow therethrough; passing a gas through the discharge zone, exposing a side of the second dielectric barrier away from the discharge zone to the liquid; and applying a voltage to the high voltage electrode sufficient to generate a plasma in the gas in the discharge zone.

In another embodiment, the method treats water which contains a microbial and/or chemical contaminant, the method comprising: providing an apparatus for treating the water with a plasma, said apparatus comprising a first dielectric barrier which is gas-impermeable and a second dielectric barrier which is porous, said first and second dielectric barriers defining a discharge zone therebetween, and a high voltage electrode which is electrically insulated from the discharge zone by the first dielectric barrier, wherein discharge zone is configured to accept a gas flow therethrough; passing a gas through the discharge zone and through the second dielectric barrier, exposing a side of the second dielectric barrier away from the discharge zone to the water; and applying a voltage of between about 1 and about 150 kV RMS to the high voltage electrode.

In another embodiment, the method comprises: providing an apparatus for treating a liquid with a plasma, said apparatus comprising a first dielectric barrier and a second dielectric barrier, said first and second dielectric barriers defining a discharge zone therebetween, and a high voltage electrode which is electrically insulated from the discharge zone by the first dielectric barrier, wherein the second dielectric barrier is gas-permeable and the discharge zone is configured to accept a gas flow therethrough; passing a gas through the discharge zone, exposing a side of the second dielectric barrier away from the discharge zone to the liquid; and applying a voltage to the high voltage electrode sufficient to generate a plasma in the gas in the discharge zone; wherein the pressure difference across the second dielectric barrier is sufficient to cause the gas to pass from the discharge zone into the liquid.

In a third aspect of the invention there is provided use of water treated using the apparatus of the first aspect, or treated using the method of the second aspect, for human consumption.

In a fourth aspect of the invention there is provided a process for preparing potable water comprising applying the method of the second aspect to contaminated water.

In a fifth aspect of the invention there is provided use of water treated using the apparatus of the first aspect, or treated using the method of the second aspect, for irrigating seeds, crops or other plants or for creating chemistry to be used as a fuel.

In a sixth aspect of the invention there is provided a method for irrigating seeds, crops or other plants comprising treating water using the apparatus of the first aspect, or treating water using the method of the second aspect, and applying the water so treated to the seeds, crops or other plants or to soil in which the seeds, crops or other plants are disposed or are growing.

In the fifth and sixth aspects of the invention, the gas may be a nitrogen containing gas, or may be nitrogen itself, whereby the method of the second aspect generates nitrogenous species in the water which are beneficial to plant growth. In these aspects, plant growth nutrients and/or hormones and/or essential minerals may be added to the treated water subsequent to applying the method of the second aspect so as to further enhance the beneficial properties of the water.

This invention may also be said broadly to consist in the parts, elements and features referred to or indicated in the specification of the application, individually or collectively, and any or all combinations of any two or more of said parts, elements or features, and where specific integers are mentioned herein which have known equivalents in the art to which this invention relates, such known equivalents are deemed to be incorporated herein as if individually set forth.

Other aspects of the invention are also disclosed.

### BRIEF DESCRIPTION OF THE DRAWINGS

Notwithstanding any other forms which may fall within the scope of the present invention, embodiments of the invention will now be described, by way of example only, with reference to the accompanying drawings in which:

FIG. 1 is an apparatus in accordance with one embodiment of the present invention; and

FIG. 2 is an apparatus in accordance with another embodiment of the present invention.

FIG. 3 is a graph showing the production of reactive oxygen species (OH·, H₂O₂, O₃) generated using the method of the present invention. Data curves show hydrogen peroxide (H₂O₂) [∘]; ozone (O₃) [♦]; hydroxyl radical (OH·) [▪] generation over time [mg/L]. The gas used is atmospheric air. The liquid is water.

FIG. 4A shows a graphs of nitrite production as a function of gas flowrate (SLM: standard litres per minute) employing the design from FIG. 1 with ground (i.e. an earthed electrode [IN]) directly in the water at 20° C.; and FIG. 4B shows the effect of water temperature on nitrite generation under the conditions of FIG. 4A with a gas flowrate of 0.5 SLM.

FIG. 5 shows an example of the plasma gas excitation spectrum for air inside the reactor, showing the presence of excited nitrogen and oxygen species. The discharge is dominated by the excited nitrogen molecules and the first negative N₂+ transition induced by the energetic electron collisions with O₂ and N₂ molecules. Hydroxyl and atomic oxygen radicals are also evident.

FIG. 6 is a photograph showing the apparatus in operation using CO₂ as the supply gas, with the plasma discharge evident within the forming bubbles leaving the reactors. The setup consists of two reactors with 12 microholes of 200 μm diameter.

FIG. 7 is a photograph showing plasma discharges within forming bubbles leaving the porous reactor. In this case the gas is argon.

FIG. 8 is an apparatus in accordance with one embodiment of the present invention.

### DETAILED DESCRIPTION

An apparatus and method of producing a non-equilibrium atmospheric plasma in water are described. A range of gases and gas mixtures can be used with the approach including; air, nitrogen, oxygen, helium, neon, argon, carbon dioxide and mixtures of any combination of any two or more of these. It will be understood that the species generated from a plasma derived from these different gases will be different and may therefore be put to different uses. By use of common general knowledge and routine trial and error, the skilled person will be readily able to determine a suitable gas or combination of gases for a specific application. For example, the gas or mixture suitable for destroying viruses may be different to that suitable for destroying PFAS or other chemical contaminants. It will be similarly understood that different operating parameters may be appropriate for different gases used in the apparatus, and these may also be readily determined by the skilled person by reference to common general knowledge and/or by routine trial and error as well as to the guidance provided herein. Operating parameters that may need to be adjusted include gas flow rate, pressure across the second dielectric barrier, voltage supplied to the high voltage electrode, whether the earthed electrode is in electrical contact with the liquid or is electrically insulated therefrom etc. Some or all of these parameters may also be adjusted to accommodate different scales of the apparatus. For example an apparatus according to the invention which is designed to treat 1 L/minute of water may require different operating parameters (voltage, gas flow rate etc.) to an apparatus designed to treat 1 m³/minute. Also, as will be well understood, the dimensions of these two apparatuses will be different. Appropriate sizing can be readily determined without inventive input.

In the context of the present invention, the term “dielectric barrier” refers to an entity which separates two regions electrically, i.e. it divides one region from another and has high electrical resistivity. It may be physically permeable or may be physically impermeable or may be physically selectively permeable.

The method may be employed to treat water or create plasma-activated water (PAW) for material decontamination, sterilization and plant growth promotion. The reactor (i.e. the portion of the apparatus consisting of the first and second dielectric barriers, the discharge zone therebetween and the high voltage electrode) is designed to be at least partially submerged in a liquid to be treated. This liquid may act as the earth, or a separate earth electrode may be provided. The separate earth electrode, if present, may be in electrical contact with the liquid, either in the form of a discrete electrode in electrical contact with the liquid or in the form of an earthed vessel in which the liquid is contained, or else it may be electrically insulated from the liquid by means of a dielectric material. In the present invention, the term “dielectric” may be considered to refer to a substance with an electrical resistivity of between 0.01 and 1015 Ω·m. Suitable dielectrics for any or all of the first dielectric barrier, the second dielectric barrier and the dielectric material (if present) include ceramics, glasses and polymeric materials, e.g. glass, quartz, silica, aluminosilicate, polyolefins, fluoropolymers, polyamides, polyimides etc. Any of the dielectrics used in the present invention may, independently, have a resistivity of from about 0.01 to about 1015 Ω·m, or about 1 to 1015, 103 to 1015, 107 to 1015, 1010 to 1015, 0.01 to 1010, 0.01 to 105, 0.01 to 10, 0.01 to 1, 1 to 1010, 105 to 1010 or 100 to 107 Ω·m, e.g. about 0.01, 0.1, 1, 10, 100, 1000, 104 105, 106, 107, 108, 109, 1010, 1011, 1012, 1013, 1014 or 1015 Ω·m.

The second dielectric barrier is permeable to the gas and or plasma discharge. It may be porous. It may have controlled porosity to facilitate interfacing and interaction of both the plasma discharge and plasma afterglow with the liquid. The second dielectric barrier may be hydrophobic, so as to prevent or inhibit an aqueous liquid from penetrating through it to the discharge zone and/or to facilitate passage of gas from the discharge zone through the second dielectric barrier. Alternatively it may be hydrophilic. In the event that the second dielectric barrier is porous, the pore size may be such as to prevent or inhibit leakage of the liquid into the discharge zone. A suitable gas pressure within the discharge zone may also serve to inhibit such leakage. Suitable pore sizes are from about 0.1 to about 2000 microns, or from about 0.1 to 1000, 0.1 to 500, 0.1 to 100, 0.1 to 50, 0.1 to 10, 1 to 2000, 10 to 2000, 100 to 2000, 500 to 2000, 500 to 1000, 1 to 1000, 1 to 100, 10 to 1000, 10 to 100 or 10 to 500 microns, e.g. about 0.1, 0.5, 1, 2, 5, 10 15, 20, 25, 30, 35, 40, 45, 50, 60, 70, 80, 90, 100, 150, 200, 250, 300, 350, 400, 450, 500, 600, 700, 800, 900, 1000, 1100, 1200, 1300, 1400, 1500, 1600, 1700, 1800, 1900 or 2000 microns. These may, independently, be maximum or mean pore sizes. Suitable pressure differences across the second dielectric barrier are at least about 10 kPa, or at least about 20, 30, 40, 50, 60, 70, 80, 90 or 100 kPa, or from about 10 to about 100 kPa, or about 10 to 50 10 to 20, 20 to 100, 50 to 100 or 20 to 50 kPa, e.g. about 10, 15, 20, 25, 30, 34, 40, 45, 50, 60, 70, 80, 90 or 100 kPa. This pressure may be generated by adjusting the flow rate of the gas through the discharge zone and/or by constricting the outlet (if present) from the discharge zone. In some instances there is no outlet from the discharge zone other than the porous second dielectric barrier. In this case, all gas passing into the discharge zone exits through the second dielectric barrier, taking with it plasma and/or byproducts from the plasma. Thus in one form of the invention, the pressure difference across the second dielectric barrier is sufficient to cause gas and/or plasma to pass from the discharge zone into the liquid. This causes bubbles to form in the liquid. Plasma and/or plasma byproducts can then pass across the gas liquid barrier into the liquid so as to treat the liquid. In general, the finer the pore size of the second dielectric barrier, the smaller the bubbles that will be formed in the liquid, and hence the greater the gas-liquid interfacial area. Increasing the interfacial area increases the transfer rate and hence renders the treatment more efficient. As the pore size is reduced, however, the flow rate through the second dielectric barrier also reduces for a particular pressure across the second dielectric barrier. Thus a suitable combination of pore size and pressure should be used to achieve a desired level of treatment efficiency. This combination may readily be determined by routine experimentation. If bubbles are to form within the liquid surrounding the second dielectric barrier, it is preferable for the liquid to be in contact with, or connected to, the outer atmosphere so as to prevent a build-up of pressure in the liquid.

A range of plasma control parameters may be controlled in the apparatus including, discharge gap (i.e the thickness of the discharge zone), discharge volume (i.e. the volume of the discharge zone), voltage and frequency to produce controlled plasma reactive species in the water. A suitable discharge gap is from about 1 to about 50 mm, or about 1 to 40, 1 to 30, 1 to 20, 1 to 10, 10 to 50, 20 to 50, 30 to 50, 40 to 50, 10 to 30 or 20 to 40 mm, e.g. about 1, 2, 3, 4, 5, 6, 7, 8, 9, 10, 15, 20, 25, 30, 35, 40, 45 or 50 mm. The discharge volume will depend on the discharge gap and the length of the discharge zone. In general, the size of the discharge zone will depend on the desired throughput of liquid to be treated. A suitable discharge volume is from about 10-2 to about 105 cm3, or about 10-2 to 102, 10-2 to 1, 1 to 105, 102 to 105, 10-2 to 2*104, 1 to 103 or 10-1 to 10 cm3, e.g. about 10-2, 5*10-2, 0.1, 0.5, 1, 5, 10, 50, 100, 500, 1000, 5000, 104, 2*104, 5*104 or 105 cm3. A suitable discharge voltage is about 1 to about 150 kV, or about 1 to 100, 1 to 50, 1 to 10, 10 to 150, 50 to 150, 100 to 150 or 50 to 100 kV, e.g. about 1, 2, 3, 4, 5, 6, 7, 8, 9, 10, 20, 30, 40, 50, 60, 70, 80, 90, 100, 110, 120, 130, 140 or 150 kV. The smaller the discharge gap, the lower the voltage required to generate the plasma. The applied voltage may be AC, DC or rectified AC. It may have a frequency of between about 1 and about 1012 Hz, or about 1 to 1010, 1 to 108, 1 to 106, 1 to 104, 1 to 102, 102 to 1012, 104 to 1012, 106 to 1012, 108 to 1012, 1010 to 1012, 102 to 106, 106 to 1010 or 104 to 108, e.g. about 1, 10 or 100 Hz, 1, 10 or 100 kHz, 1, 10 or 100 MHz, 1, 10 or 100 GHz or 1 THz. The method of the invention may be used for microbial or chemical decontamination for water, wastewater, food products, medical devices, or other objects where treatment with reactive water or liquids is effective.

The apparatus and/or method of the present invention may operate at a temperature between about 10 and about 90° C., or between about 20 and 90, 30 and 90, 40 and 90, 50 and 90, 60 and 90, 70 and 90, 80 and 90, 10 and 80, 10 and 70, 10 and 60, 10 and 50, 10 and 40, 10 and 30, 10 and 20, 20 and 50, 50 and 80 or 20 and 40° C., e.g. about 10, 15, 20, 25, 30, 35, 40, 45, 50, 55, 60, 65, 70, 75, 80, 85 or 90° C.

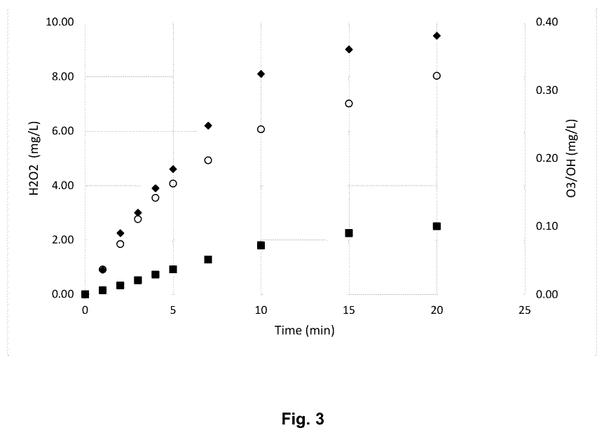

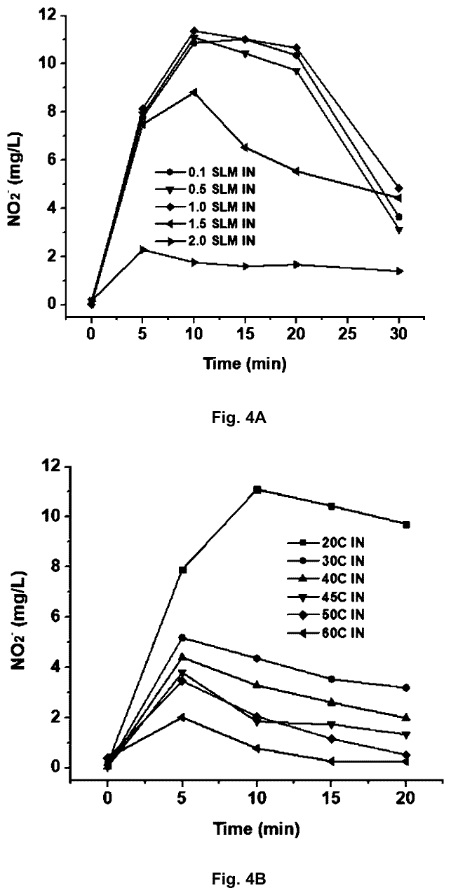

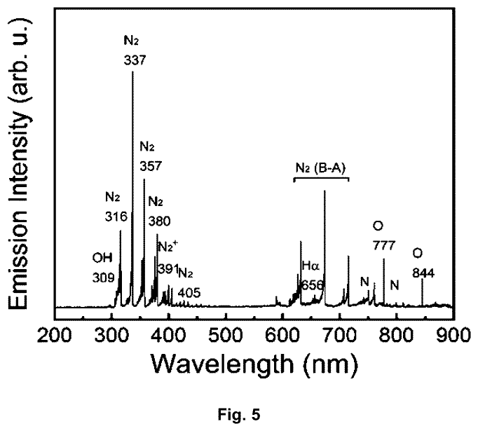

The reactive species created in the plasma may include Reactive Oxygen and Nitrogen Species (RONS), which usually include long-lived species like hydrogen peroxide (H2O2), ozone (O3), nitrate (NO3-) and nitrite (NO2-), and (relatively) short-lived species such as hydroxyl radical (OH·), nitric oxide (NO·), atomic oxygen (O), peroxynitrate (OONO2-) and peroxynitrites (ONOO—/ONOOH). An example of data on the reactive oxygen species (OH·, H2O2, O3) generated using the method of the present invention is shown in FIG. 3. An example of NO2-production as a function of gas flowrate and water temperature is shown in FIGS. 4A and 4B. FIG. 5 shows an example of the gas excitation spectrum for air, showing excited nitrogen and oxygen species in-situ within the reactor discharge gap. These species can lead to a lowering of the pH of the liquid. PAW can be used as an antimicrobial agent against bacteria, biofilms, fungi, amoebae and viruses. Similarly, it can breakdown chemical contaminants such as pesticides, antibiotics, pharmaceuticals and per- and poly-fluoroalkyl substances (PFAS). It can also be used as a plant fertilizer by utilizing nitrogen species produced such as nitrates and subsequently applied to plants or cells. Due to the reduction in pH, it may be necessary to adjust the pH of the liquid after treatment and prior to use. It may be necessary to neutralize the liquid.

An atmospheric non-thermal plasma reactor is presented herein as a means to treat water and/or generate of PAW. As the reactor and associated apparatus are readily scaleable, the apparatus is capable of being sized so as to treat large quantities of liquid and/or to have high liquid throughput. Thus the apparatus may be readily scaled so as to treat anywhere between about 1 to about 10,000 L/hour or more, or about 1 to 1000, 1 to 100, 1 to 10, 10 to 10,000, 100 to 10,000, 1000 to 10,000 or 500 to 5000 L/h, e.g. about 1 5, 10, 20, 50, 100, 200, 500, 1000, 2000, 5000 or 10,000 L/h or more than 10,000 L/h. Parameters to be scaled in order to adjust the throughput include the diameter of the discharge zone, the discharge gap, the length of the discharge zone, the gas flow rate, the volume of the vessel containing the liquid etc. In some instances, more than one reactor, e.g. 2, 3, 4, 5, 6, 7, 8, 9 or 10, or more than 10 (a reactor being, as discussed earlier, the assembly of high voltage electrode, first and second dielectric barriers and the discharge zone between these barriers) may be immersed in the same body of liquid so as to increase the rate of treatment of the liquid. These may have the same dimensions and may operate at the same voltage, or may be different dimensions and/or may operate at different voltage.

In some embodiments the liquid is treated batchwise. In other embodiments, the liquid is treated continuously. In such embodiments, the flow rate of the liquid through the apparatus may be controlled so as to provide effective treatment. If the flow rate is too high, insufficient plasma/plasma byproducts will contact the water to provide effective treatment.

In one form the reactor includes a high voltage electrode and a plasma discharge zone in the form of a Dielectric Barrier Discharge (DBD) with a gas inlet to the discharge zone. Thus the DBD comprises (or consists of) a first and a second dielectric barrier and the discharge zone therebetween. The first, commonly inner, dielectric barrier, which covers or surrounds the high voltage electrode for the DBD, may be made of quartz, glass, ceramic or polymeric material. The second, commonly outer, dielectric barrier surrounds the first dielectric barrier, so as to define the discharge zone between the first and second dielectric barriers. In one example of the DBD in use, the reactor is submerged in water, with the water acting as the ground electrode, and is earthed either directly with a submerged electrode or electrically conductive water vessel or indirectly on the outside of a non-conductive water vessel. The direct insertion of the ground metal into the water changes the resulting chemistry of the reactor, with it acting as an electrochemical electrode. The second, commonly outer, dielectric barrier is porous to the flowing inducer gas, which acts as the gas outlet and the mechanism for introducing the plasma species to the water.

According to one aspect of the invention, the water is part of the apparatus, acting as the ground electrode for the DBD. The means by which this circuit is completed is important to the resultant chemistry. At least two options are considered. The first option is to use a remote electrode to the DBD which is submerged in the water to complete the electrical circuit. The second is to complete the circuit by grounding the wall of a non-metallic water vessel. For the first approach electrochemical reactions can take place at the electrode, which will be governed by its construction material and surface area.

The outer barrier of the DBD may act not only as the outer wall of the discharge zone, maintaining the gas gap and a dielectric layer facilitating a stable plasma discharge, but also as the means for interfacing the plasma with the water. The controlled porosity of the second dielectric barrier means that gas plasma species can exit the DBD reactor. The pore size is designed to be sufficiently small to prevent an influx of water to the discharge gap. The pore size is also important in governing the size distribution of the bubbles formed. The porous DBD design minimises the time taken to introduce the reactive species formed into the liquid. However, the design permits more than merely the reactive gas species (plasma afterglow) formed in the discharge zone to be introduced. As the inducer gas passes through the pores, the plasma itself can exit and interface with the surrounding water. This approach not only increases the likelihood of introducing the short-lived species to the water but also may introduce solvated electrons into the water. UV light can also pass from the discharge zone through the outer dielectric barrier if it is constructed from a UV transmissive material such as quartz. The UV light may be generated by the plasma. It may assist in destroying contaminants in the water, in particular microorganisms and viruses.

The DBD design can be scaled by the use of concentric tubes, where the annular gap of the discharge zone is dictated by the gas and discharge voltage gas input. However the discharge volume per unit length can be increased by employing larger diameter inner and outer dielectric barriers for the DBD whilst maintaining the same gap between them. The discharge gap can therefore remain constant as the radii of both the inner and outer tubes are similarly increased. This design facilitates large volumes of gas breakdown without increasing the discharge gap, i.e. the distance between the two dielectric barriers.

By submerging the DBD reactor in the water, the apparatus has an effective heat sink to remove possible build-up of thermal energy by using natural forced convection. This may be enhanced if the apparatus is used in a continuous mode, i.e. if the water flows past the second dielectric barrier, thereby removing the heat from the overall system. The use of mixer elements can be used to increase convective heat transfer, but also governs the quantity of meta-stable and/or unstable species from the plasma in the bulk solution through mixing of the species with the bulk fluid. Suitable mixer elements may be present in the liquid, including active elements such as powered mixer blades and passive elements such as baffles. In some instances, there may be a cooler in contact with the liquid in order to facilitate the heat removal. This may be a simple heat exchanger, jacketed vessel or may be any other suitable form of cooler.

The apparatus may comprise a gas flow controller to control the volume of gas introduced to the discharge zone, the residence time of the gas in the discharge zone, the partial pressure in the discharge zone and the size of the bubbles which form in the liquid. In the event that a mixture of gases is fed to the discharge zone, there may be a gas mixer for mixing the gases in a desired proportion. This may be located before the gas inlet so that the gases are mixed before entering the discharge zone. Alternatively, a supply of suitably mixed gases may be used.

The apparatus may be powered by a pulsed AC voltage, a positive or negative DC voltage, or pulsed Radio Frequency voltage.

The second dielectric barrier, interfacing the gas and liquid, may be actively vibrated through ultrasonic waves, e.g. from about 20 kHz to about 1 MHz (or from about 20 to 500, 20 to 100, 20 to 50, 50 to 1000, 100 to 1000, 500 to 1000, 100 to 500 or 200 to 700 kHz, e.g. about 20, 30, 40, 50, 60, 70, 80, 90, 100, 150, 200, 250, 300, 350, 400, 450, 500, 600, 700, 800, 900 or 1000 kHz) to produce controlled bubbles in the nano- or micro-meter range. Small diameter bubbles are known to be more stable than larger ones and also to provide a larger interfacial surface area. This therefore may facilitate transfer of plasma and/or plasma byproducts into the liquid.

In certain embodiments of the invention the first dielectric barrier is absent. In such embodiments, the discharge zone is defined between the high voltage electrode and the second dielectric barrier. The high voltage electrode is therefore in contact with a gas in and/or passing through the discharge zone.

In certain embodiments, the second dielectric barrier is non-porous and/or impermeable to a gas in and/or passing through the discharge zone. In such embodiments, an outlet from the discharge zone is distinct from, although commonly in contact with, the second dielectric barrier. The outlet is disposed and designed to allow gas and/or discharge products to pass from the discharge zone into a liquid. This may therefore lead to treatment of the liquid by the gas and/or discharge products.

The described embodiments above (absence of the first dielectric barrier and non-porous second dielectric barrier) may be used separately or they may be combined.

Thus the present invention provides a system for treating or activating optionally large volumes of water or liquids, comprising an apparatus configured to create an atmospheric plasma while submerged in water, the apparatus typically having: a high voltage electrode, an inner dielectric barrier surrounding the high voltage electrode, a discharge zone for flowing gas and a gas-permeable, generally porous, dielectric outer barrier interfacing the plasma and the water. The bulk water may act as the ground electrode. It may additionally or alternatively act as a heat sink. The discharge gap may therefore be maintained between non-porous and porous dielectric barriers. The working gas may be air or it may comprise at least two gases selected from air, nitrogen, oxygen, carbon dioxide and a noble gas. The plasma discharges may be directly contacted with water through the porous outer dielectric barrier. Plasma induced reactive gas species may be directly contacted with water through the porous second dielectric barrier. The voltage applied to the high voltage electrode may be at least about 1 kV RMS and a maximum of about 150 kV RMS.

The invention also provides a method of sterilizing or breaking down contaminants in water comprising immersing the apparatus described earlier herein in a volume of water to be treated, flowing a working gas or gases into the discharge zone of the apparatus; and inducing a plasma in the working gas using a high voltage differential between the high voltage electrode and the grounded water.

The invention further provides a method of producing plasma activated water (PAW) comprising immersing the apparatus in a volume of water to be treated; flowing a working gas or gases into the discharge zone of the apparatus; and inducing a plasma in the working gas using a high voltage differential between the high voltage electrode and the grounded water;

### Embodiments

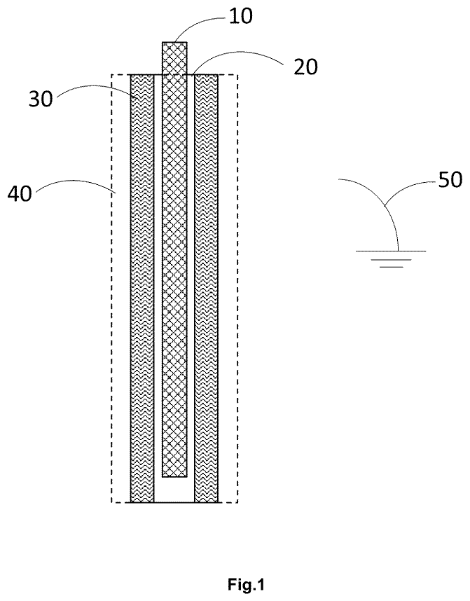

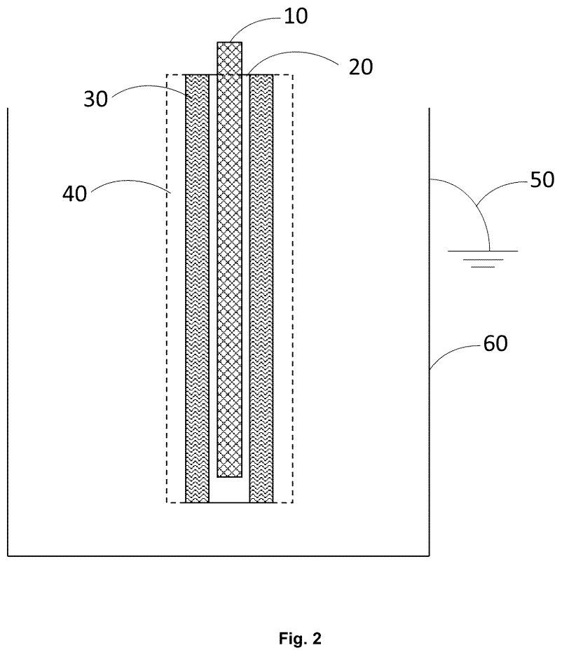

FIGS. 1 and 2 show diagrammatic representations of the apparatus of the present invention. A high voltage generator (not shown) is connected to high voltage metallic electrode 10. First dielectric barrier 20 surrounds high voltage electrode 10 to form a sheathed electrode. The effect of dielectric barrier 20 is to limit the current flowing between electrode 10 and earth and to prevent the formation of arcs. Dielectric barrier 20 also physically separates high voltage electrode 10 from discharge zone 30, which surrounds dielectric barrier 20 and prevents contact between high voltage electrode 10 and any water which may enter discharge zone 30 due to insufficient pressure within discharge zone 30. Discharge zone 30 is maintained between the outer surface of inner dielectric barrier 20 and the inner surface of outer dielectric barrier 40. The distance of the gap between inner dielectric barrier 20 and outer dielectric barrier 40 (i.e. the thickness of discharge zone 30) dictates the breakdown voltage required for a specific gas. Outer dielectric barrier 40 is porous in order to allow gas and/or plasma to pass from discharge zone 30, where plasma is generated, to water in contact with outer dielectric barrier 40. In FIG. 1, the water in contact with outer dielectric barrier 40 is earthed by means of metallic earth connection 50, whereas in FIG. 2 earth connection 50 is coupled to non-metallic vessel 60 which contains the water.

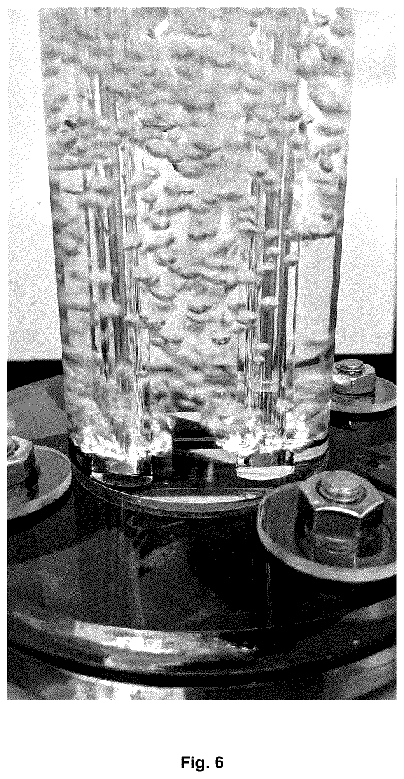

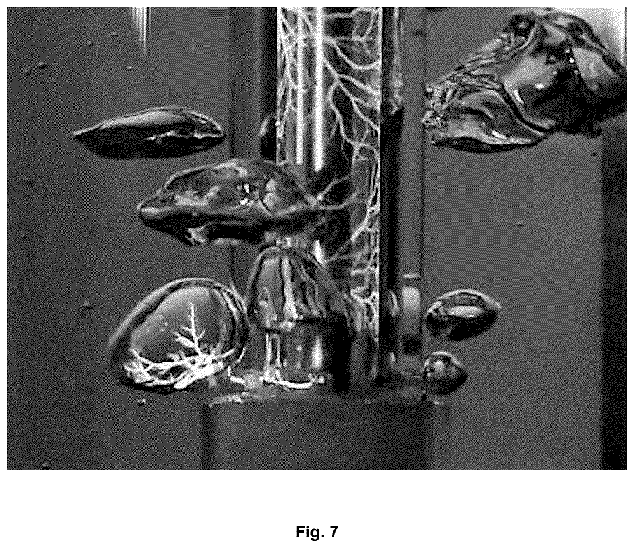

In operation, inducer gas enters discharge zone 30 through an inlet valve and exits through porous outer dielectric barrier 40. Porous dielectric barrier 40, acts as both a means of maintaining the gap of discharge zone 30 and of interfacing the plasma discharge and its reactive species into the surrounding water. When a suitably high voltage is applied to high voltage electrode 10, a plasma is formed in the inducer gas flowing through discharge zone 30. As the inducer gas passes into the water surrounding outer dielectric barrier 40, it takes with it plasma and/or plasma byproducts which treat the water. These may serve to kill microorganisms in the water and/or destroy or degrade noxious chemicals therein They may also be used as chemicals such as fertilizers and fuels. FIG. 6 shows the apparatus in operation using CO₂ as the supply gas, with the plasma discharge evident within the forming bubbles leaving the reactor's microholes. FIG. 7 shows plasma discharges within forming bubbles leaving the porous reactor.

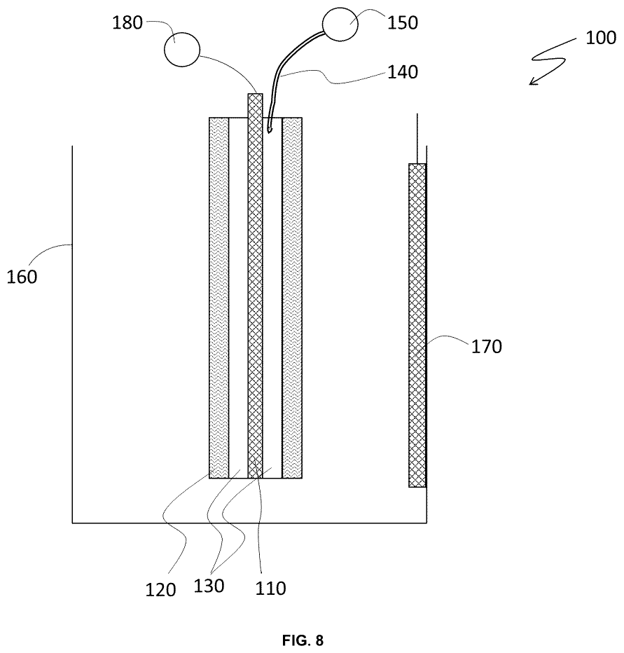

FIG. 8 shows an embodiment of the present invention. In FIG. 8, apparatus 100 comprises high voltage electrode 110 and dielectric barrier 120, which define discharge zone 130 therebetween. Dielectric barrier 120 is porous, and hence gas permeable. Discharge zone 130 is fitted with gas inlet 140, connected to gas propulsion device 150 (e.g. a pump) for propelling gas into and through discharge zone 130. Apparatus 100 also comprises vessel 160 for containing a liquid during operation of the said apparatus. It is also fitted with earthed electrode 170, which is disposed within vessel 160, so that, in operation, it is in electrical and physical contact with liquid in vessel 160. In some forms of the invention, earthed electrode 170 is instead separated from the liquid by a dielectric barrier. Finally, high voltage electrode 110, which, in operation, is in contact with gas in discharge zone 130, is electrically connected to high voltage generator 180, which provides the required high voltage to electrode 110.

In operation, therefore, a liquid to be treated is disposed in vessel 160, either in contact with, or, in some forms of the invention separated from by a dielectric barrier, the liquid. A gas is propelled into discharge zone 130 through inlet 140 by means of propulsion device 150. A high voltage is generated by generator 180 and applied to high voltage electrode 110. Gas passes through dielectric barrier 120 into the liquid in vessel 160, forming bubbles in the liquid. The high voltage between electrodes 110 and 160 gives rise to a spark discharge within these bubbles. Resulting discharge products pass into the liquid so as to treat it.

### Interpretation

### Markush Groups

[61] In addition, where features or aspects of the invention are described in terms of Markush groups, those skilled in the art will recognise that the invention is also thereby described in terms of any individual member or subgroup of members of the Markush group.

### Chronological Sequence

For the purpose of this specification, where method steps are described in sequence, the sequence does not necessarily mean that the steps are to be carried out in chronological order in that sequence, unless there is no other logical manner of interpreting the sequence.

### Embodiments

Reference throughout this specification to “one embodiment” or “an embodiment” means that a particular feature, structure or characteristic described in connection with the embodiment is included in at least one embodiment of the present invention. Thus, appearances of the phrases “in one embodiment” or “in an embodiment” in various places throughout this specification are not necessarily all referring to the same embodiment, but may. Furthermore, the particular features, structures or characteristics may be combined in any suitable manner, as would be apparent to one of ordinary skill in the art from this disclosure, in one or more embodiments.

Similarly it should be appreciated that in the above description of example embodiments of the invention, various features of the invention are sometimes grouped together in a single embodiment, figure, or description thereof for the purpose of streamlining the disclosure and aiding in the understanding of one or more of the various inventive aspects. This method of disclosure, however, is not to be interpreted as reflecting an intention that the claimed invention requires more features than are expressly recited in each claim. Rather, as the following claims reflect, inventive aspects lie in less than all features of a single foregoing disclosed embodiment. Thus, the claims following the Description of the Invention are hereby expressly incorporated into this Description of the Invention, with each claim standing on its own as a separate embodiment of this invention.

Furthermore, while some embodiments described herein include some but not other features included in other embodiments, combinations of features of different embodiments are meant to be within the scope of the invention, and form different embodiments, as would be understood by those in the art. For example, in the following claims, any of the claimed embodiments can be used in any combination.

### Different Instances of Objects

As used herein, unless otherwise specified the use of the ordinal adjectives “first”, “second”, “third”, etc., to describe a common object, merely indicate that different instances of like objects are being referred to, and are not intended to imply that the objects so described must be in a given sequence, either temporally, spatially, in ranking, or in any other manner.

### Specific Details

In the description provided herein, numerous specific details are set forth. However, it is understood that embodiments of the invention may be practiced without these specific details. In other instances, well-known methods, structures and techniques have not been shown in detail in order not to obscure an understanding of this description.

### Terminology

In describing the preferred embodiment of the invention illustrated in the drawings, specific terminology will be resorted to for the sake of clarity. However, the invention is not intended to be limited to the specific terms so selected, and it is to be understood that each specific term includes all technical equivalents which operate in a similar manner to accomplish a similar technical purpose.

For the purposes of this specification, the term “plastic” shall be construed to mean a general term for a wide range of synthetic or semisynthetic polymerization products, and generally consisting of a hydrocarbon-based polymer.

As used herein the term “and/or” means “and” or “or”, or both.

As used herein “(s)” following a noun means the plural and/or singular forms of the noun. The use of a singular noun in this specification is not intended to preclude the presence of more than one of the specified integer unless the context indicates such a limitation.

### Comprising and Including

In the claims which follow and in the preceding description of the invention, except where the context requires otherwise due to express language or necessary implication, the word “comprise” or variations such as “comprises” or “comprising” are used in an inclusive sense, i.e. to specify the presence of the stated features but not to preclude the presence or addition of further features in various embodiments of the invention. These terms should not be taken to imply any minimum proportion of the stated integer.

Any one of the terms: including or which includes or that includes as used herein is also an open term that also means including at least the elements/features that follow the term, but not excluding others. Thus, including is synonymous with and means comprising.

### Scope of Invention

Thus, while there has been described what are believed to be the preferred embodiments of the invention, those skilled in the art will recognize that other and further modifications may be made thereto without departing from the spirit of the invention, and it is intended to claim all such changes and modifications as fall within the scope of the invention. Steps may be added or deleted to methods described within the scope of the present invention.

Although the invention has been described with reference to specific examples, it will be appreciated by those skilled in the art that the invention may be embodied in many other forms.

### INDUSTRIAL APPLICABILITY

It is apparent from the above, that the arrangements described are applicable to the water purification and agricultural industries.

1. A spark-bubble discharge apparatus for treating a liquid with a plasma, the apparatus comprising:
a high voltage electrode and a gas-permeable barrier defining a discharge zone therebetween, wherein:
the gas-permeable barrier has a pore size of between 0.1 and 2000 microns, wherein a pressure difference across the gas-permeable barrier is sufficient to cause the gas to pass from the discharge zone through the gas permeable barrier into the liquid emerging in the form of gas microbubbles at the liquid/gas-permeable barrier interface;
the discharge zone is configured to accept a gas flow therethrough; and
the high voltage electrode is in contact with a gas in and/or passing through the discharge zone;
a high voltage generator adapted to supply a voltage to the high voltage electrode of between about 1 kV and about 150 kV root mean square;
a vessel for containing a liquid, whereby, in use, the liquid in the vessel is in contact with the gas-permeable barrier and is separated from the discharge zone by the gas-permeable barrier;
characterized in that a spark is generated within the forming microbubbles at or close to the gas-permeable barrier/liquid interface when a sufficient voltage is generated by the high voltage electrode,
wherein the spark produces an electric discharge in the gas phase within the microbubbles formed, producing highly reactive plasma intermediates including H₂O₂, H and OH and O radicals in the gas microbubbles allowing direct reaction between the highly reactive plasma intermediates and liquid at a gas/liquid interface in the vessel.

2. The apparatus of claim 1 further comprising an earthed electrode, said earthed electrode being separated from the discharge zone by the gas-permeable barrier.

3. The apparatus of claim 1 wherein the vessel comprises a dielectric material and the apparatus comprises an earthed electrode in contact with said dielectric material wherein the earthed electrode is disposed such that, in use, said dielectric material separates the liquid from the earthed electrode.

4. The apparatus of claim 1 further comprising an earthed electrode, said earthed electrode being disposed such that, in use, said earthed electrode is in electrical contact with the liquid in the vessel.

5. The apparatus of claim 1 wherein the high voltage electrode, the discharge zone and the gas-permeable barrier are concentric.

6. The apparatus of claim 1 wherein the gas-permeable barrier is a dielectric barrier, and wherein the gas-permeable dielectric barrier is hydrophobic.

7. The apparatus of claim 1 further comprising a gas inlet for introducing a gas into the discharge zone and a gas propulsion device for passing the gas through the discharge zone.

8. The apparatus of claim 1 wherein the high voltage electrode is a bare electrode directly exposed to the discharge zone.

9. A method for treating a liquid with a plasma comprising:
providing an apparatus comprising a high voltage electrode and a gas-permeable barrier defining a discharge zone therebetween, wherein:
the gas-permeable barrier has a pore size of between 0.1 and 2000 microns, wherein a pressure difference across the gas-permeable barrier is sufficient to cause the gas to pass from the discharge zone through the gas permeable barrier into the liquid emerging in the form of gas microbubbles at the liquid/gas-permeable barrier interface;
the discharge zone is configured to accept a gas flow therethrough; and
the high voltage electrode is in contact with a gas in and/or passing through the discharge zone;
providing a high voltage generator adapted to supply a voltage to the high voltage electrode of between about 1 kV and about 150 kV root mean square;
providing a vessel for containing a liquid, whereby, in use, the liquid in the vessel is in contact with the gas-permeable barrier and is separated from the discharge zone by the gas-permeable barrier;
passing a gas through the discharge zone wherein a pressure difference across the gas permeable barrier is sufficient to cause the gas to pass from the discharge zone through the gas-permeable barrier interfacing with the liquid in the form of gas microbubbles at the liquid/gas-permeable barrier interface;
exposing a side of the gas-permeable barrier away from the discharge zone to the liquid; and
applying a voltage to the high voltage electrode sufficient to generate a spark wherein the spark produces an electric discharge in the gas phase microbubbles producing highly reactive plasma intermediates including H₂O₂, H and OH and O radicals in the gas microbubbles, allowing direct reaction between the highly reactive plasma intermediates and liquid at the gas/liquid interface in the vessel.

10. The method of claim 9 wherein the gas is selected from the group consisting of air, nitrogen, oxygen, carbon dioxide, helium, neon, argon, xenon and mixtures of any two or more of these.

11. The method of claim 9 wherein the gas is air.

12. The method of claim 9 wherein the liquid is an aqueous liquid.

13. The method of claim 9 wherein the liquid comprises a contaminant, whereby the method at least partially removes and/or destroys said contaminant.

14. The method of claim 13 wherein the contaminant is selected from the group consisting of microorganisms and chemical contaminants.

15. The method of claim 14 wherein the contaminant comprises one or more of pharmaceuticals, endocrine disruptors and PFAS.
